(19) United States
(12) Patent Application Publication
(10) Pub. No.: US 2018/0248121 A1
(43) Pub. Date: Aug. 30, 2018

(54) Printable Functional Materials For Plastic Electronics Applications

(71) Applicant: DST Innovations Limited, Bridgend (GB)

(72) Inventors: Anthony Miles, Bridgend (GB); Stephen Robert Hughes, Beddau (GB); Niladri Vyas, Swansea (GB)

(73) Assignee: DST Innovations Limited, Bridgend (GB)

(21) Appl. No.: 15/554,998

(22) PCT Filed: Mar. 2, 2016
(86) PCT No.: PCT/GB2016/050538

§ 371 Date: Aug. 31, 2017

(30) Foreign Application Priority Data
Mar. 3, 2015 (GB) 1503570.2

(51) Int. Cl. H01L 51/00; H01L 51/50; H01L 51/52; H01L 51/42; H01L 51/44

(52) U.S. Cl. CPC H01L 51/0034; H01L 51/0004; H01L 51/0022; H01L 51/5012; H01L 2251/308; H01L 51/4253; H01L 51/442; H01L 51/0037; H01L 51/5234

(57) ABSTRACT

A printable active material formulation comprises a matrix comprising a gelation material and a solvent; and at least one conductive material. A printable cathode formulation comprises a matrix comprising a thermoplastic resin and a solvent; and at least one conductive material. An organic light emitting or photovoltaic device may be manufactured using these formulations, for example by roll-to-roll printing.

### FIELD OF THE INVENTION

The present invention relates to a printable formulation, such as an active material or printable cathode formulation, and a method of manufacturing the printable formulation. The present invention further relates to an organic light emitting or photovoltaic device comprising the printable formulation, and a method of manufacturing the same.

### BACKGROUND OF THE INVENTION

The following discussion is not to be taken as an admission of relevant prior art.

Polymer based electronics or plastic electronics mainly deal with organic materials that display attractive electronic properties that are useful for manufacturing polymer based electronic devices including light emitting diodes and solar cells. Both small molecule organic light emitting diodes (OLEDs) and organic solar cells (OSCs) were first reported by Kodak in 1985 and 1986 respectively, followed by the discovery of polymer OLEDs by Burroughes, Friend, and Bradley in 1988. OLEDs and OSCs possess similar device architecture in terms of the arrangement of functional materials in a layered fashion, and the materials normally used to manufacture such devices are sometimes common for both. For instance, conductive polymers such as Poly(3,4-ethylenedioxythiophene)-poly(styrenesulfonate) (PEDOT:PSS), Poly(9,9-di-n-octylfluorenyl-2,7-diyl) (PFO), Poly[2-methoxy-5-(2-ethylhexyloxy)-1,4-phenylenevinylene] (MEH-PPV) and Poly(3-hexylthiophene-2,5-diyl) (P3HT) can be used to manufacture both OLEDs and OSCs.

However, in order to produce a layered architecture, sequential deposition of functional materials in a continuous manner is essential for manufacturing large area devices in a roll-to-roll production facility. Thus, efforts have been made to introduce printing techniques such as ink-jet and screen printing to manufacture multilayered OLEDs and OSCs with optimum device performance (US 20140087507 A1; U.S. Pat. No. 7,287,469 B2). In most cases ink-jet printing is suitable for manufacturing small scale devices. However, this technique is very time consuming and not suitable for the manufacturing of large area devices. In addition, print heads used in this technique are expensive and tend to break very easily.

A study reported by Pardo et al. (D. A. Pardo, G. E. Jabbour, N. Peyghambarian, Application of Screen Printing in the Fabrication of Organic Light-Emitting Devices, Adv. Mater. 2000, 12, No. 17, 2000) features a blend of N′-diphenyl-N, N′-bis-3-methylphenyl [1,1′-biphenyl]-4, 4′-diamine (TPD) and a polycarbonate matrix that acts as a screen printable hole-transport layer (HTL) in AlQ₃ based OLEDs. However, the AlO₃ layer and the cathode were vacuum deposited in this study for producing high efficiency OLEDs. Another study by Victor et al. (U.S. Pat. No. 6,605,483 B2) describes screen printing of MEH-PPV based light emitting polymer diodes where the active material (MEH-PPV) was blended with polystyrene to produce a printable composition using high vapour pressure solvents. The thickness of the screen printed MEH-PPV film was very high which severely affected the brightness of the fabricated devices. Furthermore, due to the application of vacuum deposited cathode, this study was unable to provide fully screen printable functional materials for OLED application. Similarly, due to the incorporation of evaporated metal cathode of a specific work-function, organic solar cells are also not fully screen printable to date at low cost (B. Qi, Z. G. Zhang, J. Wang, Uncovering the role of cathode buffer layer in organic solar cells, Scientific Reports 5, Article number: 7803, Nature, 2015). In addition, high vapour pressure solvents in the printable compositions make the screen printing very difficult as solvents with high vapour pressure evaporate very quickly during the printing process, causing imperfections.

Roll-to-roll printing is possible using a variety of techniques such as lithography, flexography, rotogravure, and screen printing, and the majority have already been shown to be provide the possibility of printing either OLED or OSC devices. However, each technique offers a different unique challenge. In flexography, lithography, and rotogravure, a common problem is the back transfer of solutions due to poor surface compatibility of the ink to the substrate and also shrinkage of the transferred media.

### SUMMARY OF INVENTION

According to a first aspect of the invention, there is provided a printable formulation comprising: a matrix comprising a gelation material and a solvent; and at least one conductive material. Advantageously, the printable formulation of the present invention may be used to manufacture large-scale organic light emitting and/or photovoltaic devices in a roll-to-roll production facility (such as a screen printing production facility) without the requirement of a cleanroom.

Preferably, the gelation material comprises a cellulose derivative. Advantageously, the use of a cellulosic matrix (i.e. a matrix comprising a cellulose derivative) improves the compatibility between the ink and the substrate and enhances the transfer of the ink to the substrate. In addition, the gel-like nature of the cellulosic matrix means the transferred material is not prone to shrinkage and therefore leads to better line definition.

Typically, the cellulose derivative comprises an O-alkyl cellulose derivative and/or O-hydroxyalkyl cellulose. It is preferred that the cellulose derivative comprises ethyl cellulose, methyl cellulose, propyl cellulose or hydroxypropylmethylcellulose. Preferably, the cellulose derivative is ethyl cellulose. Typically, the cellulose derivative dissolves within the solvent to form a three-dimensional gel matrix.

Preferably, the solvent is a low vapour pressure solvent. Advantageously, the use of a low vapour pressure solvent induces a slower evaporation rate than the use of a high vapour pressure solvent. Typically, the low vapour pressure solvent has a pressure of between 50 and 80 psi at 240° C., typically approximately 75 psi at 240° C. Typically, the solvent may be any glycol or any highly substituted benzene or higher liquid aromatic. It is preferred that the solvent is mesitylene (1,3,5-trimethylbenzene), ethylene glycol, diethylene glycol, ethylene glycol butyl ether, diethylbenzene, tetrahydronapthalene or dichlorobenzene. Advantageously, the use of a low vapour pressure solvent facilitates the printing process and is consistent for roll-to-roll manufacturing. Preferably, the solvent is mesitylene. The conductive material may be organic or inorganic.

In one embodiment, the conductive material may be a polymer. It is preferred that the polymer is a light emitting polymer. Typically, the polymer is poly(3,4-ethylenedioxythiophene)-poly(styrenesulfonate) (PEDOT:PSS), poly(9,9-di-n-octylfluorenyl-2,7-diyl) (PFO), poly[2-methoxy-5-(2-ethylhexyloxy)-1,4-phenylenevinylene] (MEH-PPV) or poly(3-hexylthiophene-2,5-diyl) (P3HT).

In one embodiment, the printable formulation may further comprise a thickener. Typically, the thickener comprises corn starch, guar gum or xanthan gum. In one embodiment, the matrix may comprise polystyrene, chloroform and a thickener.

Preferably, the printable formulation is provided in the form of a nanocomposite blend with tunable electronic properties.

According to a second aspect of the present invention, there is provided a printable cathode formulation comprising: a matrix comprising a thermoplastic resin and a solvent; and at least one conductive material. Advantageously, the provision of a printable cathode formulation avoids the requirement of a vacuum deposited cathode material for organic light emitting diodes (OLEDs) and organic solar cells (OSCs).

Preferably, the printable cathode formulation comprises two or more conductive materials. It is preferred that the printable cathode formulation comprises a low work-function material and a high work-function material. Typically, the at least one conductive material comprises a low work-function metallic material and a high work-function metallic material. Typically, the low-work function material comprises one or more of calcium, magnesium or aluminium. Typically, the high-work function material comprises one or more of tin, gold, copper, carbon, nickel, palladium, silver or platinum. In one embodiment, the at least one conductive material comprises a metal oxide, such as indium tin oxide. Advantageously, the printable cathode formulation comprising conductive materials with dissimilar work functions advantageously acts as a high performance cathode material for OLEDs and OSCs. In case of OLEDs the printable cathode composition may advantageously be able to provide low turn-on voltage with attractive device performance.

Typically, the thermoplastic resin comprises an epoxy resin such as epon 1001F (a bisphenol A epoxy resin), bisphenol F epoxy resin or novolac epoxy resins. In another embodiment, the thermoplastic resin comprises polyurethane (for example, trixene SC7913). In one embodiment, the thermoplastic resin may be cross-linked by amines (for example, polyurethane), anhydrides (for example, tetrahydrophthalic anhydride), phenols (for example, bisphenol A) or thiols.

Preferably, the printable cathode formulation comprises the solvent 2-butoxy ethanol (ethylene glycol butyl ether) or butyl carbitol (diethylene glycol butyl ether).

According to a third aspect of the present invention, there is provided a method of producing a printable formulation according to the first aspect, the method comprising the steps of: forming a matrix comprising a gelation material and a solvent; and adding at least one conductive material to the matrix.

Preferably, the gelation material comprises a cellulose derivative.

Preferably, the method further comprises the step of sonicating the gelation material and the solvent to produce a homogeneous solution.

It is preferred that the conductive material is added following sonication of the mixture.

According to a fourth aspect of the present invention, there is provided a method of producing a printable cathode formulation, the method comprising the steps of: forming a matrix comprising a thermoplastic resin and a solvent; and adding at least one conductive material to the matrix.

Preferably, the method comprises the step of adding a low work-function conductive material and a high work-function conductive material to the matrix. Preferably, the low work-function and high work-function materials are added in the form of particles. Preferably, the method comprises the use of a solution blending process.

According to a fifth aspect, there is provided an organic light emitting or photovoltaic device. It is preferred that the organic light emitting or photovoltaic device comprises the printable formulation according to the first aspect, and/or the printable cathode formulation of the second aspect.

Preferably, the device is a screen printable plastic electronic device. It is preferred that the device is an organic light emitting diode or an organic solar cell.

Preferably, the device comprises a plurality of layers. It is preferred that the plurality of layers comprise one or more of a substrate, a bottom electrode, a top electrode, a hole transport layer, an active emission layer, an electron transport layer, an electron blocking layer, a hole blocking layer, an electron injection layer and/or a photosensitive/photoactive layer.

In one embodiment, the substrate may be flexible. In another embodiment, the substrate may be rigid.

Advantageously, the printable active material formulation of the first aspect and/or the printable cathode formulation of the second aspect may be easily screen printed on any suitable substrate such as indium tin oxide (ITO) coated PET to produce large area organic light emitting diodes or photovoltaic devices with attractive performance.

According to a sixth aspect, there is provided a method of manufacturing an organic light emitting or photovoltaic device according to the fifth aspect, wherein the method comprises the step of roll-to-roll printing.

Preferably, the method comprises the step of screen printing.

In another embodiment, the method may comprise the step of flexography, lithography, ink jet printing or rotogravure.

Typically, the printable active material formulation is printed onto a substrate to produce a film having a thickness of between 200 and 300 nanometers. Advantageously, the printable formulation may be thinly printed on a flexible or rigid substrate without affecting the device performance.

Advantageously, the method allows the manufacture of fully screen printable OLEDs and OSCs.

Advantageously, screen printing of organic or inorganic electronic devices in accordance with embodiments of the present invention offers the possibility of low cost device manufacturing at large scale. Advantageously, embodiments of the present invention allow the production of fully screen printable large area organic light emitting and photovoltaic devices without the requirement for any cleanroom facility.

### DETAILED DESCRIPTION OF THE INVENTION

Specific embodiments will now be described by way of example only and with reference to the following figures wherein:

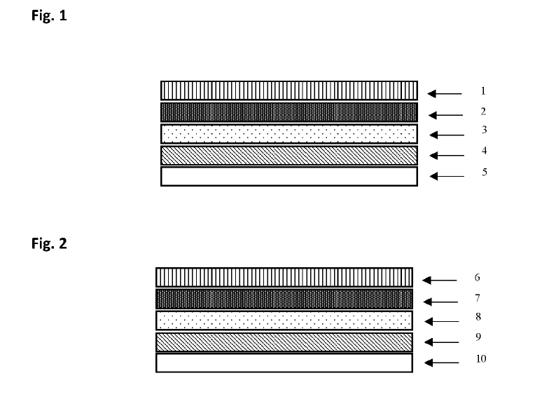

FIG. 1 illustrates a device in an embodiment of the invention, wherein the device is a simple OLED device; and

FIG. 2 illustrates a device in an embodiment of the invention, wherein the device is a simple OSC device.

The device architecture illustrated in FIG. 1 shows a simple OLED device, comprising a flexible or rigid substrate 5, an ITO or any other high work function transparent conductor (bottom electrode) 4, a hole transport layer 3, typically PEDOT:PSS, an active emissive layer 2, and a low work function metal cathode (top electrode) 1. FIG. 2 shows the design of a simple OSC device comprising a flexible or rigid substrate 10, a transparent conductor (bottom electrode) 9 of ITO or any other high work function material, an electron transport layer 8, typically PEDOT:PSS, a solar cell active polymer 7, and a low work function metal cathode (top electrode) 6.

The device architectures in FIGS. 1 & 2 are for illustrative purposes only, and these structures can be either ‘normal’ (as drawn) or ‘inverted’ with transparent top electrodes and/or made more complex with the inclusion of further layers, not limited to: hole transport layers, electron blocking layers, hole blocking layers and/or electron injection layers.

The printable active material formulation may be a screen printable nanocomposite blend containing conductive polymers which may be used for OLED and OSC applications.

In one embodiment, the method of producing the printable active material formulation comprises the steps of dispersing ethyl cellulose at a specific weight percentage into a low vapour pressure solvent such as mesitylene followed by sonication for a prolonged time in order to produce a homogenous solution. Typically, the cellulose derivative dissolves in the solvent to form a three dimensional gel matrix. This solution of ethyl cellulose in mesitylene is used as a matrix for preparing different types of nanocomposite blends by incorporating conductive polymers such as PFO, MEH-PPV and P3HT. The nanocomposite blends produced in this manner display optimum characteristics suitable for screen printing application. These formulations are ideal for screen printing onto a range of substrates including ITO coated PET and FTO coated glass producing a film thickness between 200 to 300 nanometers. In this case, devices fabricated using screen printed active materials displayed comparable brightness and photovoltaic performance to the conventional OLEDs and OSCs with vapour deposited active materials.

The printable cathode composition may be developed using solution blending process where a thermoplastic resin matrix comprising a solvent was formed, and wherein finely ground particles of a low work-function metal were mixed with relatively high work-function metal particles and subsequently loaded onto the thermoplastic resin matrix. Such a composition containing metallic particles with dissimilar work-functions acts as a high performance cathode material for OLEDs and OSCs. In case of OLEDs this composition is able to provide low turn-on voltage with attractive device performance.

### EXAMPLES

The following examples describe the fabrication of a fully screen printable organic light emitting diode using screen printable active material along with a cathode which was also deposited using a screen printing technique.

### Example 1

FIG. 1 shows the device architecture of an OLED that was fabricated on a 2″×2″ sheet of ITO coated PET (150Ω/□) which was cleaned thoroughly using isopropyl alcohol. A hole transport layer (HTL) was then screen printed onto the clean ITO substrate followed by its drying at 120° C. for 15 minutes. A conductive polymer such as PEDOT: PSS was used as a HTL in this case. The emissive layer was made of PFO which was blended with a 2.5 wt % ethyl cellulose dispersion in mesitylene. The amount of PFO in this nanocomposite blend was approximately 1.6% by weight. This nanocomposite blend of PFO and ethyl cellulose was then screen printed onto the HTL coated ITO-PET substrate followed by its curing at 120° C. for 10 minutes. Finally, a cathode material containing 33 wt % Mg and 33 wt % Ag was deposited on the top the PFO based active layer using screen printing technique. The cathode material deposited in this case normally takes 10 minutes to sinter at 120° C.

### Example 2

The same approach as described in Example 1 was used to manufacture a fully screen printable organic solar cell (FIG. 2) on a 1″×1″ flexible substrate based on ITO coated PET (60Ω/□). The substrate was first cleaned using isopropyl alcohol followed by deposition of a thin layer of PEDOT: PSS using screen printing technique. The PEDOT: PSS layer was then annealed at 120° C. for 15 minutes prior to screen printing the P3HT: PCBM/ethyl cellulose based active layer on top. The active layer was also annealed at 120° C. for 15 minutes followed by screen printing the Mg/Ag cathode as a back contact.

1. A printable active material formulation, comprising:
a matrix comprising a gelation material and a solvent; and
at least one conductive material.

2. The printable active material formulation according to claim 1, wherein the gelation material comprises a cellulose derivative.

3. The printable active material formulation according to claim 2, wherein the cellulose derivative comprises at least one of an O-alkyl cellulose derivative, a hydroxyalkyl cellulose, ethyl cellulose, methyl cellulose, propyl cellulose or hydroxypropylmethylcellulose.

4. (canceled)

5. The printable active material formulation according to claim 1, wherein the solvent is a low vapor pressure solvent.

6. The printable active material formulation according to claim 5, wherein the solvent is mesitylene (1,3,5-trimethylbenzene), ethylene glycol, diethylene glycol, ethylene glycol butyl ether, diethylbenzene, tetrahydronapthalene or dichlorobenzene.

7. The printable active material formulation according to claim 1, wherein the conductive material is a polymer.

8. The printable active material formulation according to claim 7, wherein the conductive material is a light emitting polymer.

9. The printable active material formulation according to claim 7, wherein the polymer is poly(3,4-ethylenedioxythiophene)-poly(styrenesulfonate) (PEDOT:PSS), poly(9,9-di-n-octylfluorenyl-2,7-diyl) (PFO), poly[2-methoxy-5-(2-ethylhexyloxy)-1,4-phenylenevinylene] (MEH-PVV) or poly(3-hexylthiophene-2,5-diyl) (P3HT).

10. (canceled)

11. A printable cathode formulation, comprising:
a matrix comprising a thermoplastic resin and a solvent; and
at least one conductive material.

12. The printable cathode formulation according to claim 11, wherein the formulation comprises two or more conductive materials.

13. The printable cathode formulation according to claim 11, wherein the at least one conductive material comprises a low work-function material and a high work-function material.

14. The printable cathode formulation according to claim 11, wherein at least one conductive material comprises a low work-function metallic material and a high work-function metallic material.

15. The printable cathode formulation according to claim 11, wherein the at least one conductive material comprises a metal oxide.

16. The printable cathode formulation according to claim 11, wherein the thermoplastic resin comprises polyurethane or an epoxy resin.

17. The printable cathode formulation according to claim 11, wherein the thermoplastic resin is cross-linked by amines, anhydrides, phenols or thiols.

18. The printable cathode formulation according to claim 11, wherein the solvent comprises 2-butoxy ethanol (ethylene glycol butyl ether) or butyl carbitol (diethylene glycol butyl ether).

19. A method of manufacturing a printable active material formulation according to claim 1, the method comprising the steps of:
forming a matrix comprising a gelation material and a solvent; and
adding at least one conductive material to the matrix.

20. The method according to claim 19, wherein the gelation material comprises a cellulose derivative.

21. The method according to claim 19, wherein the method further comprises the step of sonicating the gelation material and the solvent to produce a homogeneous solution.

22. The method according to claim 21, wherein the conductive material is added following sonication of the homogeneous solution of the gelation material and the solvent.

23. A method of manufacturing a printable cathode formulation in accordance with claim 11, the method comprising the steps of:
forming a matrix comprising a thermoplastic resin and a solvent; and
adding at least one conductive material to the matrix.

24. The method according to claim 23, wherein the method includes the step of adding a low work-function material and a high work-function material to the matrix.

25. The method according to claim 24, wherein the low work-function material and high work-function material are added as particles.

26-36. (canceled)
